(19) United States
(12) Patent Application Publication
(10) Pub. No.: US 2012/0196421 A1
(43) Pub. Date: Aug. 2, 2012

(54) STRESS ADJUSTING METHOD

(75) Inventors: Tsung-Hung CHANG, Linnei Township (TW); Ling-Chun CHOU, YuweiTownship (TW)

(73) Assignee: UNITED MICROELECTRONICS CORP., HSINCHU (TW)

(21) Appl. No.: 13/018,717

(22) Filed: Feb. 1, 2011

(51) Int. Cl. H01L 21/336

(52) U.S. Cl. 438/303; 257/E21.409

(57) ABSTRACT

An stress adjusting method includes the following steps. A substrate is provided. A first gate structure and a second gate structure adjacent to the first gate structure are formed on the substrate. Each of the first gate structure and the second gate structure includes a spacer. A source/drain implantation process is applied to the substrate by using the first gate structure with the spacer and the second gate structure with the spacer as a mask. After the source/drain implantation process, the spacers are thinned so as to increase a distance between the first gate structure and the second gate structure. A stress film is formed. A first annealing process is applied to the substrate having the stress film.

### FIELD OF THE INVENTION

The present invention relates to a stress adjusting method, and particularly to a stress adjusting method, which is applied to a fabrication of an integrated circuit.

### BACKGROUND OF THE INVENTION

Because a length of a gate can not be limitlessly reduced any more and new materials have not been proved to be used in an integrated circuit (e.g., a metal-oxide-semiconductor field-effect transistor (MOSFET)), adjusting mobility has been an important role to improve the performance of the integrated circuit. A lattice strain of a channel is widely applied to increase mobility during fabricating the integrated circuit. For example, the hole mobility of a silicon with the lattice strain can be 4 times as many as the hole mobility of a silicon without the lattice strain, and the electron mobility of the silicon with the lattice strain can be 1.8 times as many as the electron mobility of the silicon without the lattice strain. Therefore, a tensile stress can be applied to an N-channel of an N-channel MOSFET by changing the structure of the transistor, or a compression stress can be applied to a P-channel of a P-channel MOSFET by changing the structure of the transistor. The channel is stretched, which can improve the electron mobility, and the channel is compressed, which can improve the hole mobility.

Stress memorization technique (SMT) is a method for adjusting mobility. In the SMT method, an amorphous implantation process is applied to a source/drain region of the MOSFET so as to change monocrystalline silicon into amorphous silicon in the source/drain region. And then, a stress film is formed on the amorphous silicon in the source/drain region. Afterwards, a thermal process, for example, an annealing process is performed so that the source/drain region can memorize the stress effect of the stress film, thereby generating the lattice strain of the channel. However, with the increase of the integrated degree of the semiconductor components, a distance between two adjacent gate structures 10 become narrower and narrower. When the stress film 12 is formed, the surfaces of a portion of the stress film 12 between the two adjacent gate structures 10 are prone to merge, thereby forming a merge structure 120 as shown in FIG. 1. Thus, the original stress of the stress film 12 is released. As a result, the channel 11 of the MOSFET can not obtain an entire stress memorization effect.

Therefore, what is needed is a stress adjusting method to overcome the above disadvantages.

### SUMMARY OF THE INVENTION

The present invention provides a stress adjusting method, which is applied to a fabrication of an integrated circuit and is capable of obtaining an entire stress memorization effect.

The present invention provides a stress adjusting method, which includes the following steps. A substrate is provided. A first gate structure and a second gate structure adjacent to the first gate structure (especially two gate structures of two adjecant N-type MOSFETs) are formed on the substrate. Each of the first gate structure and the second gate structure includes a spacer. A source/drain implantation process is applied to substrate by using the first gate structure with the spacer and the second gate structure with the spacer as a mask. After the source/drain implantation process, the spacers are thinned so as to increase a distance between the first gate structure and the second gate structure. A stress film is formed to cover the first gate structure with the thinned spacer, the second gate structure with the thinned spacer and a surface of the substrate exposed from the first gate structure with the thinned spacer and the second gate structure with the thinned spacer. A first annealing process is applied to the substrate having the stress film.

In one embodiment of the present invention, each spacer includes a first spacer and a second spacer.

In one embodiment of the present invention, the first spacer is either a composite layer structure including a silicon oxide layer and a silicon nitride layer, or a pure silicon oxide layer, and the second spacer is either a composite layer structure including a silicon oxide layer and a silicon nitride layer.

In one embodiment of the present invention, the spacers are thinned by a dry etching process, or a wet etching process, or a combination of the dry etching process and the wet etching process.

In one embodiment of the present invention, the step of thinning the spacers is either to reduce a transverse thickness of the second spacer or to remove the second spacers.

In one embodiment of the present invention, an etchant of the wet etching process is phosphoric acid (H3PO4) when the second spacer comprises silicon nitride.

In one embodiment of the present invention, the stress film is selected from a group consisting of a silicon oxide layer, a silicon nitride layer, a composite layer including a silicon oxide layer and a silicon nitride layer.

In one embodiment of the present invention, the stress film is a tensile stress film.

In one embodiment of the present invention, the first annealing process is selected from a group consisting of a rapid thermal process, a laser annealing process and a combination of a rapid thermal process and a laser annealing process.

In one embodiment of the present invention, the adjusting method further includes the following steps. The stress film is etched by a dry etching process so as to form a third spacer corresponding to the first gate structure and the second gate structure respectively. A salicide block (SAB) layer is formed to cover the first gate structure with the third spacer, the second gate structure with the third spacer and a surface of the substrate exposed from the first gate structure with the third spacer and the second gate structure with the third spacer.

In one embodiment of the present invention, the salicide block layer is selected from a group consisting of a silicon oxide layer, a silicon nitride layer, a composite layer including a silicon oxide layer and a silicon nitride layer.

In one embodiment of the present invention, the adjusting method further includes the following steps. A photoresist pattern is form on the stress film. Then, the stress film is etched by a dry etching process so as to form a forth spacer corresponding to the second gate structure. The photoresist pattern is removed so as to expose the remaining stress film to form a salicide block layer.

In one embodiment of the present invention, after the source/drain implantation process and before forming the stress film, alternatively, a second annealing process is performed.

In one embodiment of the present invention, the second annealing process is selected from a group consisting of a rapid thermal process, a laser annealing process and a combination of a rapid thermal process and a laser annealing process.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 illustrates a schematic view of a merge structure of a stress film in conventional MOSFET.

FIGS. 2A-2E illustrate a process flow of a stress adjusting method in accordance with an embodiment of the present invention.

FIGS. 3A-3B illustrate a process flow of removing a stress film in accordance with an embodiment of the present invention.

FIGS. 4A-4B illustrate a process flow of removing a stress film in accordance with another embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

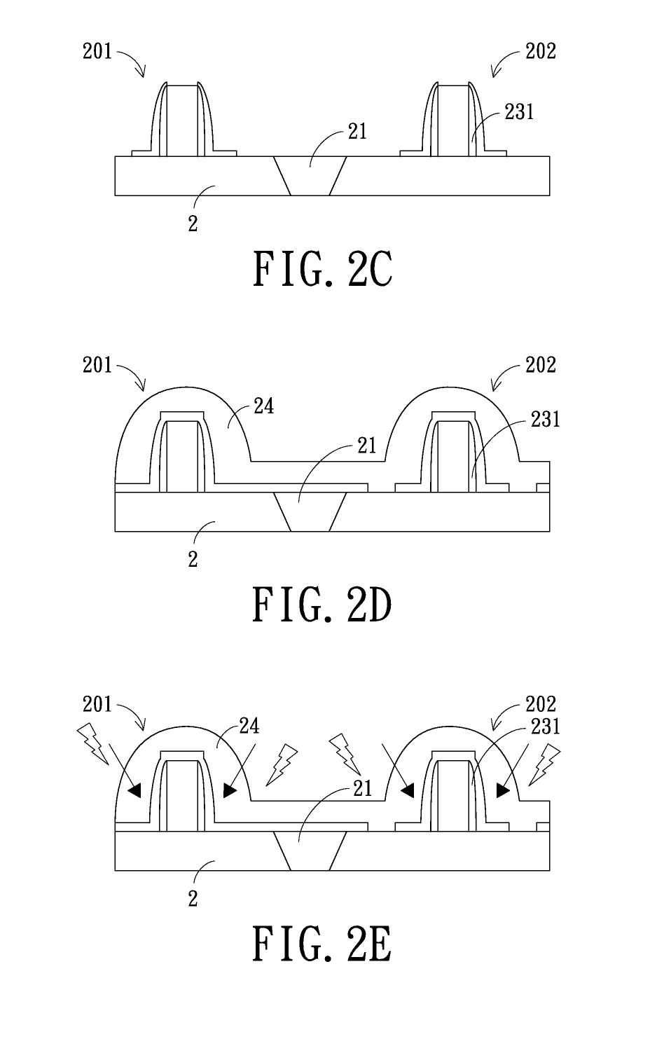

FIGS. 2A-2E illustrate a process flow of a stress adjusting methodin accordance with an embodiment of the present invention. Referring to FIG. 2A, a substrate, for example, a silicon substrate 2 is provided. A number of gate structures are formed on the silicon substrate 2 by a general process for fabricating a MOSFET. For example, in the present embodiment, a first gate structure 201 of an N-type MOSFET and a second gate structure 202 of a P-type MOSFET are formed on the silicon substrate 2. In other embodiment, a first gate structure 201 of an N-type MOSFET and a second gate structure 202 of a N-type MOSFET can be formed on the silicon substrate 2. An isolation structure 21 is formed between the first gate structure 201 and the second gate structure 202. Each of the first gate structure 201 and the second gate structure 202 includes a spacer 23. The spacer 23 can be a multilayer structure shown in FIG. 2A, which includes a first spacer 231 and a second spacer 232. The first spacer 231 can be either a composite layer structure including a silicon oxide layer and a silicon nitride layer, or a pure silicon oxide layer. The second spacer 232 can be either a composite layer structure including a silicon oxide layer and a silicon nitride layer.

Referring to FIG. 2B, two source/drain implantation processes is respectively applied to the silicon substrate 2 by using the first gate structure 201 with the spacer 23 and the second gate structure 202 with the spacer 23 as a mask respectively, thereby forming a respective source/drain region of the N-type MOSFET and the P-type MOSFET. It is noted that, a respective source/drain region of two adjacent N-type MOSFETs can be formed by a source/drain implantation process simultaneously. After the source/drain implantation process is finished, the spacers 23 are thinned. The spacers 23 can be thinned, for example, by a dry etching process, or a wet etching process, or a combination of the dry etching process and the wet etching process. Thus, a transverse thickness of each of the second spacers 232 is reduced. It is noted that, a longitudinal thickness (height) may be reduced simultaneously. In addition, the second spacers 232 can be removed entirely. In the present embodiment, as shown in FIG. 2C, the second spacers 232 are removed entirely. An etchant of the wet etching process is phosphoric acid (H3PO4) when the second spacer comprises silicon nitride.

Next, referring to FIG. 2D, after the spacers 23 are thinned, a stress film 24 is formed to cover the first gate structure 201 with the spacer 231 (i.e., the thinned spacer 23), the second gate structure 202 the spacer 231 and a surface of the substrate 2 exposed from the first gate structure 201 with the spacer 231 and the second gate structure 202 with the spacer 231. The stress film 24 can be a single layer or a multilayer structure. For example, the stress film 24 can be a silicon oxide layer, a silicon nitride layer, or a composite layer including a silicon oxide layer and a silicon nitride layer. In the present embodiment, the stress film 24 is a composite layer. Therefore, at first, the silicon oxide layer is deposited, and then the silicon nitride layer is deposited on the silicon oxide layer. In the present embodiment, the stress film 24 is a tensile stress film. Referring to FIG. 2E, a first annealing process is applied to the silicon substrate 2 having the stress film 24. The first annealing process can includes a step of performing a rapid thermal process, a step of performing a laser annealing process, and a step of performing combination of a rapid thermal process (RTP) and a laser annealing process. The RTP process is applied to the source/drain region and a temperature is more than 550° C. In addition, a second annealing process can also be performed after the source/drain implantation process and before forming the stress film 24. The second annealing process can be selected from a group consisting of a rapid thermal process, a laser annealing process and a combination of a rapid thermal process and a laser annealing process.

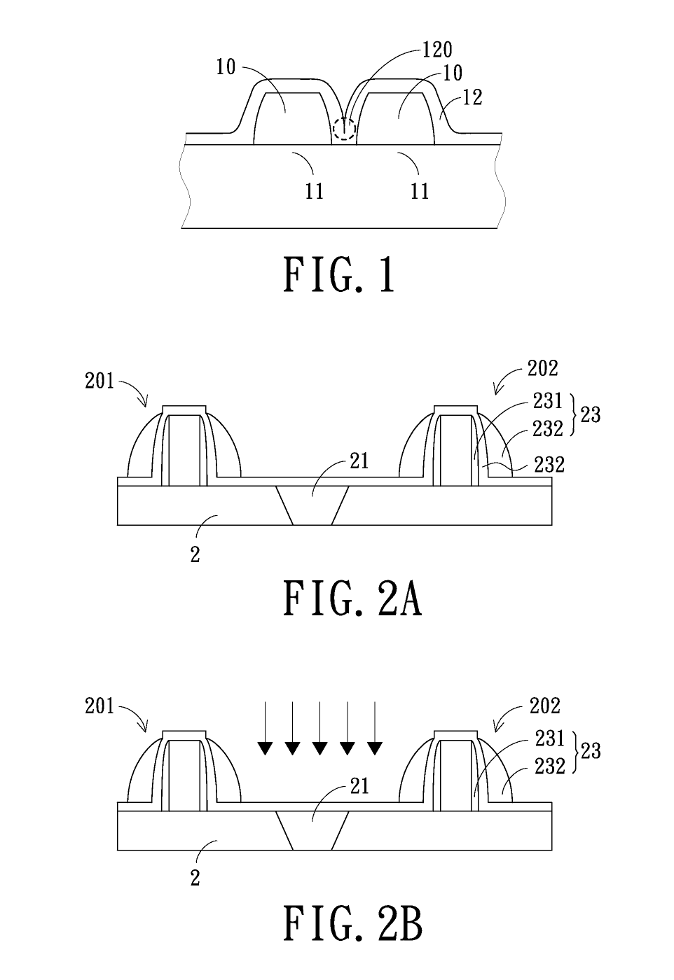

After the aforesaid processes, the distance between two adjacent N-type MOSFETs can be increased effectively. Thus, the merge structure 120, as shown in FIG. 1, will not be formed, thereby either keeping the original stress or increase film thickness to get more strain of the stress film 24. Further, the stress film 24 can be closer to the channel. As a result, an entire stress memorization effect can be obtained.

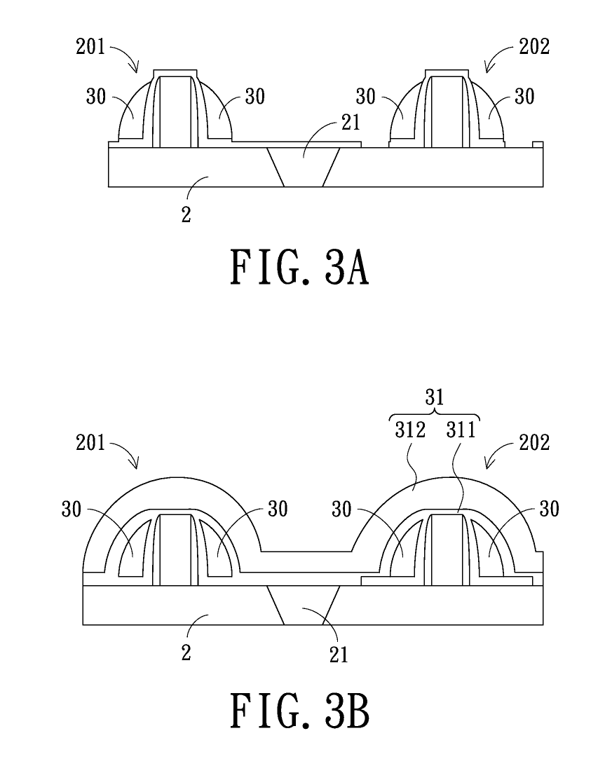

A method for removing the stress film 24 will be described as follows. Two embodiments are provided. In one embodiment, referring to FIG. 3A, first, the stress film 24 is etched by a dry etching process. The remaining stress film 24 forms a third spacer 30 corresponding to the first gate structure 201 and a third spacer 30 corresponding to the second gate structure 202 respectively. Thus, a profile of the first gate structure 201 having the third spacer 30 is similar to a profile of the first gate structure 201 having the second spacer 232, and a profile of the second gate structure 202 having the third spacer 30 is similar to a profile of the second gate structure 202 having the second spacer 232. Next, referring to FIG. 3B, a salicide block layer 31 is formed to cover the first gate structure 201 with the third spacer 30, the second gate structure 202 with the third spacer 30 and a surface of the silicon substrate 2 exposed from the first gate structure 201 with the third spacer 30 and the second gate structure 202 with the third spacer 30. The salicide block layer 31 can be, for example, a silicon oxide layer, a silicon nitride layer, a composite layer including a silicon oxide layer and a silicon nitride layer. In the present embodiment, the salicide block layer 31 is a composite layer including a silicon oxide layer 311 and a silicon nitride layer 312. The salicide block layer 31 is configured for a subsequent salicide process. Afterwards, a portion of the salicide block layer 31 can be removed so as to expose a region where the salicide process will form. For example, in the present embodiment, the portions of the salicide block layer 31 on the first gate structure 201 and the second gate structure 202 can be removed. The portions of the salicide block layer 31 can be remained on an electrostatic discharge region and a resistance where the salicide process will not form. The profiles of the first gate structure 201 and the second gate structure 202 are similar to the profiles of the first gate structure 201 and the second gate structure 202 having the second spacers 232, which is directed to ensure an exact location of the salicide. Thus, the salicide will not be close to the channel.

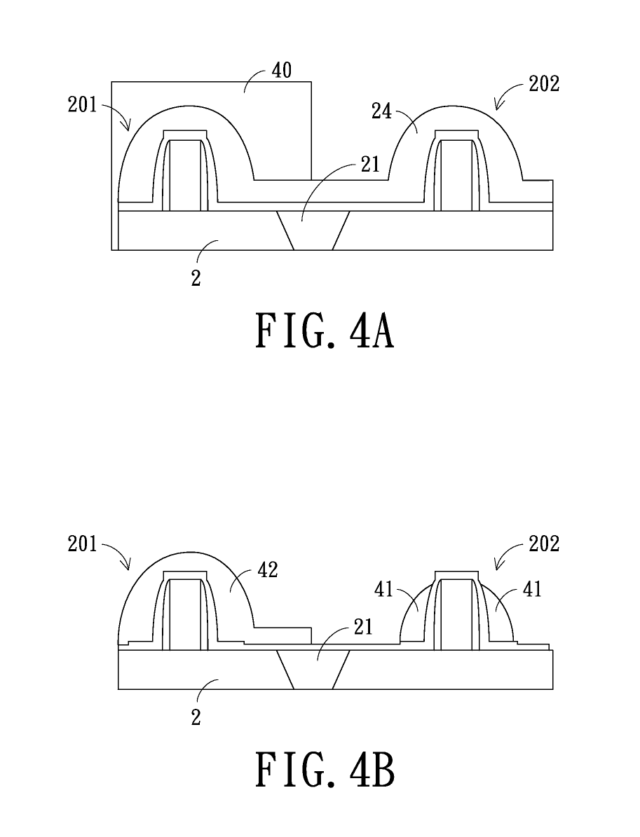

In another embodiment, the salicide block layer is directly formed by the stress film 24. In detail, referring to FIG. 4A, at first, a photoresist pattern 40 is formed by a mask (not shown) on the stress film 24. A portion of the stress film 24 covered by the photoresist pattern 40 is configured for forming the salicide block layer. Then, the stress film 24 is etched by a dry etching process to remove an exposed portion of the stress film 24 so as to form a fourth spacer 41 corresponding to the second gate structure 202. A profile of the second gate structure 202 having the fourth spacer 41 is similar to the profile of the second gate structure 202 having the second spacer 232. Thereafter, referring to FIG. 4B, the photoresist pattern 40 is removed so as to expose the remaining stress film 24 to form a salicide block layer 42. The salicide block layer 42 is configured for a subsequent salicide process. For example, in the present embodiment, the second gate structure 202 is a device structure where the salicide process will form. Thus, a portion of the salicide block layer 42 on the second gate structure 202 is removed. The portion of the salicide block layer 42 is remained on an first structure 201 where the salicide process will not form.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A stress adjusting method, comprising:
providing a substrate;
forming a first gate structure and a second gate structure adjacent to the first gate structure on the substrate, each of the first gate structure and the second gate structure comprising a spacer;
applying a source/drain implantation process to the substrate by using the first gate structure with the spacer and the second gate structure with the spacer as a mask;
after the source/drain implantation process, thinning the spacers so as to increase a distance between the first gate structure and the second gate structure;
forming a stress film to cover the first gate structure with the thinned spacer, the second gate structure with the thinned spacer and a surface of the substrate exposed from the first gate structure with the thinned spacer and the second gate structure with the thinned spacer; and
applying a first annealing process to the substrate having the stress film.

2. The stress adjusting method as claimed in claim 1, wherein the substrate is a silicon substrate, and the spacer comprises a first spacer and a second spacer.

3. The stress adjusting method as claimed in claim 2, wherein the first spacer is either a composite layer structure comprising a silicon oxide layer and a silicon nitride layer, or a pure silicon oxide layer, and the second spacer is either a composite layer structure comprising a silicon oxide layer and a silicon nitride layer.

4. The stress adjusting method as claimed in claim 2, wherein the step of thinning the spacers is to reduce a transverse thickness of the second spacer.

5. The stress adjusting method as claimed in claim 2, wherein the step of thinning the spacers is to remove the second spacers.

6. The stress adjusting method as claimed in claim 1, wherein the spacers are thinned by a dry etching process, or a wet etching process, or a combination of the dry etching process and the wet etching process.

7. The stress adjusting method as claimed in claim 6, wherein an etchant of the wet etching process is phosphoric acid (H₃PO₄) when the second spacer comprises silicon nitride.

8. The stress adjusting method as claimed in claim 1, wherein the stress film is selected from a group consisting of a silicon oxide layer, a silicon nitride layer, a composite layer comprising a silicon oxide layer and a silicon nitride layer.

9. The stress adjusting method as claimed in claim 1, wherein the stress film is a tensile stress film.

10. The stress adjusting method as claimed in claim 1, wherein the first annealing process comprises a rapid thermal process.

11. The stress adjusting method as claimed in claim 1, wherein the first annealing process comprises a laser annealing process.

12. The stress adjusting method as claimed in claim 1, wherein the first annealing process comprises:
performing a rapid thermal process; and
performing a laser annealing process.

13. The stress adjusting methodas claimed in claim 1, further comprising:
etching the stress film by a dry etching process so as to form a third spacer corresponding to the first gate structure and the second gate structure respectively; and
forming a salicide block layer to cover the first gate structure with the third spacer, the second gate structure with the third spacer and a surface of the substrate exposed from the first gate structure with the third spacer and the second gate structure with the third spacer.

14. The stress adjusting method as claimed in claim 13, wherein the salicide block layer is selected from a group consisting of a silicon oxide layer, a silicon nitride layer, a composite layer comprising a silicon oxide layer and a silicon nitride layer.

15. The stress adjusting method as claimed in claim 1, further comprising:
forming a photoresist pattern on the stress film;
etching the stress film by a dry etching process so as to form a forth spacer corresponding to the second gate structure; and
removing the photoresist pattern so as to expose the remaining stress film to form a salicide block layer.

16. The stress adjusting method as claimed in claim 1, wherein a second annealing process is performed after the source/drain implantation process and before forming the stress film.

17. The stress adjusting method as claimed in claim 1, wherein the second annealing process is selected from a group consisting of a rapid thermal process, a laser annealing process and a combination of a rapid thermal process and a laser annealing process.
